(19) United States
(12) Patent Application Publication
(10) Pub. No.: US 2008/0148132 A1
(43) Pub. Date: Jun. 19, 2008

(54) Error detection and correction scheme for multi-level cell NAND flash

(76) Inventor: Rajith K. Mavila, Austin, TX (US)

Correspondence Address: TROP, PRUNER & HU, P.C., 1616 S. VOSS RD., SITE 750, HOUSTON, TX, 77057-2631, US

(21) Appl. No.: 11/588,475

(22) Filed: Oct. 26, 2006

(51) Int. Cl. H03M 13/00

(52) U.S. Cl. 714/779

(57) ABSTRACT

An error detection and correction scheme for multi-level cell memory arrays is disclosed. By separating adjacent bits of data into multiple bit streams, the likelihood of error correction is increased.

### BACKGROUND

### DESCRIPTION OF THE RELATED ART

Bit errors are sometimes introduced into stored or transmitted data due to, for example, electrical interference or thermal noise. Error correction methods allow data that is read or transmitted to be checked for errors and, when necessary, corrected.

Common error correction schemes involve storing redundant information as a code with a unit of data that can be used to determine if errors have been introduced. A new code is calculated as the data is read and compared to the stored code. If the codes are the same, the data does not contain an error. The stored code may be used to reconstruct the data if an error is detected.

Common error correction schemes include error correcting codes (ECC), Hamming codes, BCH, and Reed-Solomon codes. One disadvantage of most error correction schemes is that typically only single bit errors can be detected and corrected. Multiple bit errors can be corrected, for example, using BCH and Reed-Solomon codes, but the implementations are complex and costly.

### BRIEF DESCRIPTION OF THE DRAWINGS

The present invention may be better understood, and its numerous features and advantages made apparent to those skilled in the art by referencing the accompanying drawings.

FIG. 1 illustrates an error detection and correction system according to an embodiment of the present invention.

FIG. 2 illustrates an error detection and correction flow diagram according to an embodiment of the present invention.

FIG. 3 illustrates a flash interface system according to an embodiment of the present invention.

FIG. 4 illustrates error detection and correction logic according to an embodiment of the present invention.

The use of the same reference symbols in different drawings indicates similar or identical items.

### DESCRIPTION OF THE EMBODIMENT(S)

In the following description, numerous specific details are set forth. However, it is understood that embodiments of the invention may be practiced without these specific details. In other instances, well-known methods, structures and techniques have not been shown in detail in order not to obscure an understanding of this description.

References to “one embodiment,” “an embodiment,” “example embodiment,” “various embodiments,” etc., indicate that the embodiment(s) of the invention so described may include a particular feature, structure, or characteristic, but not every embodiment necessarily includes the particular feature, structure, or characteristic. Further, repeated use of the phrase “in one embodiment” does not necessarily refer to the same embodiment, although it may.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

Unless specifically stated otherwise, as apparent from the following discussions, it is appreciated that throughout the specification discussions utilizing terms such as “processing,” “computing,” “calculating,” or the like, refer to the action and/or processes of a computer or computing system, or similar electronic computing device, that manipulate and/or transform data represented as physical, such as electronic, quantities into other data similarly represented as physical quantities.

In a similar manner, the term “processor” may refer to any device or portion of a device that processes electronic data from registers and/or memory to transform that electronic data into other electronic data that may be stored in registers and/or memory. A “computing platform” may comprise one or more processors.

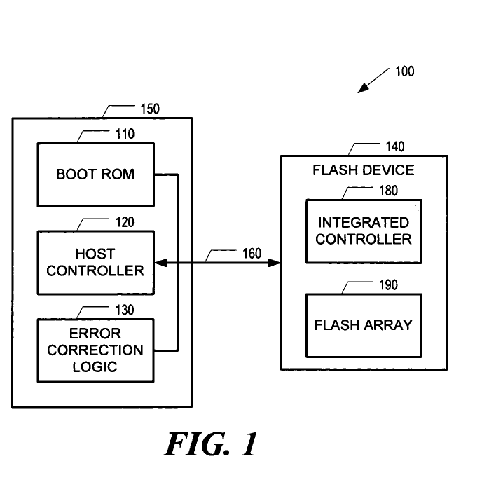

Referring to FIG. 1, an example flash memory system 100 may include a boot read-only memory (ROM) 110, a host controller 120, error detection and correction logic 130, and a flash device 140. In general, the flash memory system 100 may be implemented in an electronic device (not shown). For example, the flash memory system 100 may be implemented in a desktop computer, a network server, a laptop computer, a handheld computer, a tablet computer, a cellular telephone (e.g., a smart phone), a pager, an audio and/or video player (e.g., an MP3 player or a DVD player), a gaming device, a digital camera, a navigation device (e.g., a global position system (GPS) device), a medical device (e.g., a heart rate monitor, a blood pressure monitor, etc.), and/or other suitable relatively stationary, mobile, and/or portable electronic devices.

While the boot ROM 110, the host controller 120, and the error detection and correction logic 130 are depicted as separate blocks, these components may be integrated within a central processing unit (CPU) 150. The CPU 150 may be operatively coupled to the flash device 140 via a flash interface 160. For example, the flash interface 160 may include a bus, and/or a direct link between the boot ROM 110, the host controller 120, the error detection and correction logic 130, and the flash device 140.

In general, the boot ROM 110 may provide boot code to the flash device 140 for initializing the flash device 140. The host controller 120 (e.g., an application processor) may perform a variety of operations for the CPU 150. For example, the host controller 120 may process operations ranging from running an operating system (OS) or an application to invoking the boot ROM 110.

The flash device 140 may include an integrated controller 180 and a flash array 190. The flash array 190 may store data, code, and/or other suitable information. Flash array 190 may include multi-level cell technology, where two or more bits of information are stored in a single cell, for example, multi-level cell (MLC) NAND flash arrays. Due to the storage of multiple bits in a single cell, adjacent bit errors are more common than in other types of memories. Thus, error correction codes that can only detect and correct single bit errors used in common approaches do not meet the needs of multi-level cell memories.

While the components shown in FIG. 1 are depicted as separate blocks, the functions performed by some of these blocks may be integrated within a single semiconductor circuit or may be implemented using two or more separate integrated circuits. The methods and apparatus described herein are not limited in this regard.

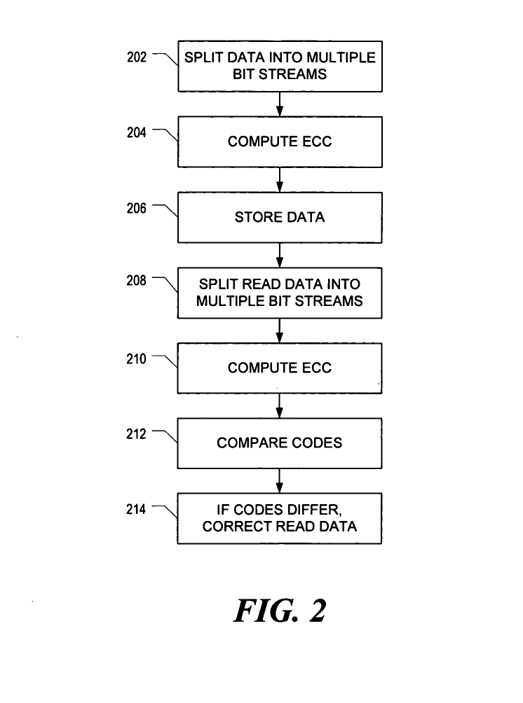

FIG. 2 illustrates an error detection and correction flow diagram according to an embodiment of the present invention. Before data is written to flash device 140, an error correction code is generated. First, the data is separated into two or more bit streams wherein adjacent bits are separated, for example, the odd bits and even bits are separated into two different bit streams, block 202. An error correction code is calculated for each bit stream, block 204. The data in its un-separated form is stored in flash device 140, block 206.

The error correction codes may be stored with the data, or in another location. The methods and apparatus described herein are not limited in this regard. The error correction codes may be stored with adjacent bits separated, for example, such that a code generated from even bits is stored in even bit positions and a code generated from odd bits is stored in odd bit positions.

Upon subsequent reads of the data, the data is again separated into two or more bit streams, block 208, and an error correction code is calculated for each bit stream, block 210. The code generated upon storing the data is compared to the code generated upon reading the data, block 212. If the codes match, there is no error. If the codes differ, the read data is corrected, block 214.

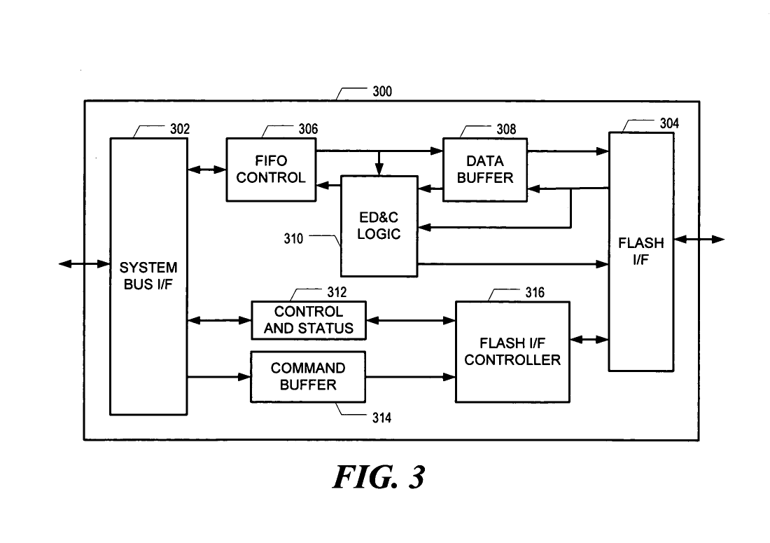

FIG. 3 illustrates a flash interface system according to an embodiment of the present invention. As illustrated, flash interface system 300 includes system bus interface logic 302 to interface to a host system (not shown) and flash interface logic 304 to interface to a flash device (not shown). The host system may read and write to the flash device through flash interface system 300. Flash interface 300 performs error detection and correction for host system data accesses utilizing FIFO 306 and data buffer 308 for buffering data before and after error detection and correction logic 310. Flash interface 300 further includes control and status logic 312, command buffer 314 and flash interface controller 316 for handling commands, status, and controls for access to the flash device.

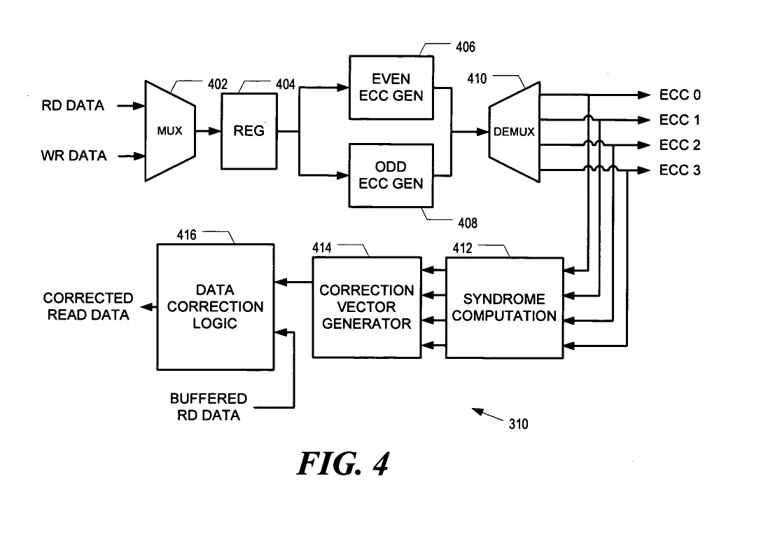

FIG. 4 illustrates error detection and correction logic according to an embodiment of the present invention. Error detection and correction logic 310 generates error correction codes for data to be written to a flash device and performs error detection and correction for data read from the flash device. Logic is reused for area savings. A multiplexer 402 selects between read data and write data which is then stored in register 404. The stored data is divided into multiple bit streams separating adjacent bits, for example, dividing even and odd bits into two bit streams. Even error correction code generator 406 and odd error code generator 408 generates codes for the even and odd bit streams, respectively. According to one embodiment of the invention, for every 256 bytes in a given data stream a three byte error correction code is generated. For example, if the page size is 512 bytes each error code generator outputs three bytes each, so six bytes of error correction code is generated. If the page size is 2048 bytes, each engine goes through the computation process four times, thus generating four sets of six byte error correction codes each (ECC0-3). Any standard SEC/DED (Single error Correction/Double error detection) algorithm may be used. The error correction codes may be written to a spare area of the flash device.

When a page read is performed, error correction codes are generated on the read data using the above mentioned blocks. The stored error correction codes are also read from the spare area, and are exclusive-OR'd (XOR'ed) with the computed error correction codes to generate syndromes in syndrome computation logic 412. The computed syndrome represents an error pointer. This pointer is transformed to a 64 bit correction vector by correction vector generator 414, adjusting for the data currently in the data buffer. The appropriate bits of the correction vector change, depending on the bit error location, during the cycle the read data is output from the data buffer. Data correction is performed by XORing the correction vector bit the read data by data correction logic 416. If there are multiple errors in either of the data streams (even or odd) as indicated by the syndromes, a double bit error status bit is set and no correction is performed.

According to one embodiment of the present invention, to support a dual mode where controller data width is 16 bits and memory data width is 8 bits, implying that two devices are connected to a single chip select, another set of even and odd error correction code generators may be used.

According to one embodiment of the present invention, calculating error correction codes on separated data ensures that a single cell failure of a multi-level cell flash device can be corrected using an SEC/DED algorithm.

According to an embodiment of the present invention, error detection and correction may support two flash devices on the same chip select. The page length of the flash may be configurable so that, for example, 512 byte and 2048 byte page sizes may be supported.

The techniques described above may be embodied in a computer-readable medium for configuring a computing system to execute the method. The computer readable media may include, for example and without limitation, any number of the following: magnetic storage media including disk and tape storage media; optical storage media such as compact disk media (e.g., CD-ROM, CD-R, etc.) and digital video disk storage media; holographic memory; nonvolatile memory storage media including semiconductor-based memory units such as FLASH memory, EEPROM, EPROM, ROM; ferromagnetic digital memories; volatile storage media including registers, buffers or caches, main memory, RAM, etc.; and data transmission media including permanent and intermittent computer networks, point-to-point telecommunication equipment, carrier wave transmission media, the Internet, just to name a few. Other new and various types of computer-readable media may be used to store and/or transmit the software modules discussed herein. Computing systems may be found in many forms including but not limited to mainframes, minicomputers, servers, workstations, personal computers, notepads, personal digital assistants, various wireless devices and embedded systems, just to name a few. A typical computing system includes at least one processing unit, associated memory and a number of input/output (I/O) devices. A computing system processes information according to a program and produces resultant output information via I/O devices.

Realizations in accordance with the present invention have been described in the context of particular embodiments. These embodiments are meant to be illustrative and not limiting. Many variations, modifications, additions, and improvements are possible. Accordingly, plural instances may be provided for components described herein as a single instance. Boundaries between various components, operations and data stores are somewhat arbitrary, and particular operations are illustrated in the context of specific illustrative configurations. Other allocations of functionality are envisioned and may fall within the scope of claims that follow. Finally, structures and functionality presented as discrete components in the various configurations may be implemented as a combined structure or component. These and other variations, modifications, additions, and improvements may fall within the scope of the invention as defined in the claims that follow.

What is claimed is:

1. A method comprising:
receiving write data;
separating the write data into two or more bit streams, wherein adjacent bits of the write data are separated;
calculating a write error correction code for each of the two or more bit streams;
storing the write data as stored write data; and
storing the write error correction code for each of the two or more bit streams as stored error correction codes.

2. The method as recited in claim 1, wherein storing the write error correction code for each of the two or more bits streams comprises separating adjacent bits of the write error correction for each of the two or more bits streams in storage.

3. The method as recited in claim 1, further comprising:
reading the stored write data as read data;
separating the read data into two or more other bit streams; wherein adjacent bits of the read data are separated;
calculating a read error correction code for each of the two or more other bit streams;
comparing the stored error correction codes with the read error correction code for each of the two or more other bit streams; and
correcting the read data if an error is detected.

4. The method as recited in claim 1, wherein the stored write data is stored in a multi-level cell flash array.

5. The method as recited in claim 1, wherein separating the write data comprises separating even bits of the write data into a first bit stream and separating odd bits of the write data into a second bit stream.

6. The method as recited in claim 1, wherein correcting the read data comprises exclusive-ORing the read data with a correction vector.

7. The method as recited in claim 1, wherein a three byte error correction code is generated for every 256 bytes of write data.

8. An apparatus comprising:
a register to store write data;
two or more error correction code generators to generate error correction codes for the write data, wherein adjacent bits of the write data are sent to a different one of the two or more error correction code generators; and
a memory interface to store the write data and the error correction codes.

9. The apparatus as recited in claim 8, wherein the memory interface is further configured to separate adjacent bits of the write error correction for each of the two or more bits streams in storage.

10. The apparatus as recited in claim 8, the memory interface further to read the stored write data as read data, the two or more error correction code generators further to generate read error correction codes for the read data, wherein adjacent bits of the read data are sent to a different one of the two or more error correction code generators; the apparatus further comprising:
comparator logic to compare the error correction codes with the read error correction codes; and
correction logic to correct the read data if an error is detected.

11. The apparatus as recited in claim 8, wherein the memory interface is configured to store the write data in a multi-level cell flash array.

12. The apparatus as recited in claim 8, wherein even bits of the write data are sent to a first error correction code generator and the odd bits of the write data are sent to a second error correction code generator.

13. The apparatus as recited in claim 8, wherein a three byte error correction code is generated for every 256 bytes of write data.

14. A system comprising:
a multi-level cell flash array;
a register to store write data;
two or more error correction code generators to generate error correction codes for the write data, wherein adjacent bits of the write data are sent to a different one of the two or more error correction code generators; and
a memory interface to store the write data in the multi-level cell flash array as stored write data.

15. The system as recited in claim 14, wherein the memory interface is further configured to separate adjacent bits of error correction codes to be stored in the multi-level cell flash array.

16. The system as recited in claim 14, the memory interface further to read the stored write data as read data, the two or more error correction code generators further to generate read error correction codes for the read data, wherein adjacent bits of the read data are sent to a different one of the two or more error correction code generators; the apparatus further comprising:
comparator logic to compare the error correction codes with the read error correction codes; and
correction logic to correct the read data if an error is detected.

17. The system as recited in claim 14, wherein even bits of the write data are sent to a first error correction code generator and the odd bits of the write data are sent to a second error correction code generator.

18. The system as recited in claim 14, wherein a three byte error correction code is generated for every 256 bytes of write data.
